(19) United States
(12) Patent Application Publication
(10) Pub. No.: US 2024/0210891 A1
(43) Pub. Date: Jun. 27, 2024

(54) PIEZOELECTRIC RESONATOR WITH FLEXIBLE GUIDE, ESPECIALLY FOR CLOCK ROTARY MOTORS

(71) Applicant: The Swatch Group Research and Development Ltd, Marin (CH)

(72) Inventors: Mohammad Hussein KAHROBAIYAN, Boudevilliers (CH); Yvan FERRI, St-Aubin-sauges (CH); Alexandre DIDIER, Erlach (CH); Lionel PARATTE, Marin-Epagnier (CH); Jean-Jacques BORN, Morges (CH)

(73) Assignee: The Swatch Group Research and Development Ltd, Marin (CH)

(21) Appl. No.: 18/528,966

(22) Filed: Dec. 5, 2023

(30) Foreign Application Priority Data
Dec. 23, 2022 (EP) 22216410.5

(51) Int. Cl. G04C 3/12; F16C 11/12; H02N 2/12

(52) U.S. Cl. CPC G04C 3/12; F16C 11/12; H02N 2/123

(57) ABSTRACT

A piezoelectric resonator, in particular for a rotary piezoelectric motor, the resonator including a stationary base and an oscillating mass extending around a longitudinal axis, the oscillating mass being provided with at least one flyweight, preferably two opposing flyweights, wherein the resonator includes a flexible guide connecting the oscillating mass to the base, so as to be able to cause the oscillating mass to oscillate about a centre of rotation in a pendulum movement, the flexible guide comprising at least a first flexible blade connecting the base to the oscillating mass, the first flexible blade comprising at least in part an electrically actuatable piezoelectric material for deforming the first flexible blade and causing the oscillating mass to oscillate.

### TECHNICAL FIELD OF THE INVENTION

The invention relates to the technical field of piezoelectric resonators, in particular for rotary piezoelectric motors. The invention also relates to the technical field of timepieces fitted with such a rotary piezoelectric motor.

### TECHNOLOGICAL BACKGROUND

The electric motors usually used in watchmaking are ‘Lavet’ type rotary motors, which operate on electromagnetic physical principles. A motor of this type generally comprises a stator fitted with coils and a magnetised rotor, which rotates by shifting the phase of the coils.

However, these motors have limited resistance to high magnetic fields. Above a certain magnetic field value, the motor blocks. In general, they jam when the magnetic field exceeds 2 mT.

So, to avoid this problem, we need to design motors that operate on other physical principles.

For example, there are electrostatic motors with combs, such as the one described in patent CH709512. But combs take up space, and they consume more energy than “Lavet” type motors.

Motors based on the piezoelectric effect have also been developed, for example in patent EP0587031. However, this is limited to actuating a calendar. In addition, its high power consumption and the risk of premature wear make it impossible to drive a seconds hand, which generally requires the most energy.

### SUMMARY OF THE INVENTION

The aim of the present invention is to provide a piezoelectric resonator, in particular for a rotary piezoelectric motor, which can withstand high electromagnetic fields, while maintaining reduced power consumption and volume.

To this end, the invention relates to a piezoelectric resonator, in particular for a rotary piezoelectric motor of a timepiece, the resonator comprising a stationary base and an oscillating mass extending around a longitudinal axis, the oscillating mass being provided with at least one flyweight, preferably two opposing flyweights.

The invention is remarkable in that it comprises a flexible blade guide connecting the oscillating weight to the base, so as to be able to cause the oscillating weight to oscillate about a centre of rotation in a pendulum movement, the flexible guide comprising at least a first flexible blade connecting the base to the oscillating weight, the first flexible blade comprising at least in part an electrically actuatable piezoelectric material for deforming the first flexible blade and causing the oscillating weight to oscillate.

A resonator with such a configuration can provide movement efficiently. By actuating the piezoelectric material of the flexible blade(s), they bend so that the oscillating mass oscillates by pivoting on itself about a centre of rotation. In this way, the resonator produces an oscillatory movement of the oscillating mass, while consuming little energy, because the actuation of the flexible blade(s) requires less energy.

In addition, by choosing resonance conditions for the resonator at the resonator's natural frequency, the piezoelectric resonator, and therefore the motor, consumes little energy. Actuation at resonance gives a greater amplitude with less energy.

The oscillatory movement can thus be transmitted to other mechanical parts depending on the field of application of the piezoelectric resonator, for example to a gear wheel of a movement.

According to a particular embodiment of the invention, the centre of rotation is arranged substantially in the middle of the oscillating mass, preferably in the centre of mass of the oscillating mass.

In a particular embodiment of the invention, the flexible guide comprises a second flexible blade connecting the oscillating mass to the base or to a fixed support. The result is an elastic pivot of the RCC (remote centre compliance) type, which is an elastic rotary guide.

In a particular embodiment of the invention, the second flexible blade comprises at least in part a piezoelectric material that can be electrically actuated to deform the second flexible blade and cause the oscillating mass to oscillate.

According to a particular embodiment of the invention, the first flexible blade and the second flexible blade form an angle of between 30° and 150°, preferably between 60° and 130°, or even between 90° and 120°.

In a particular embodiment of the invention, the first flexible blade and the second flexible blade are uncrossed and extend from a central portion of the oscillating mass to eccentric portions of the base.

In a particular embodiment of the invention, the resonator comprises a third flexible blade, the second flexible blade and the third flexible blade being uncrossed and extending from a central portion of the oscillating mass to eccentric portions of the base.

According to a particular embodiment of the invention, the second flexible blade and the third flexible blade form an angle of between 30° and 150°, preferably between 60° and 130°, or even between 90° and 120°.

In a particular embodiment of the invention, the first flexible blade is arranged between the second flexible blade and the third flexible blade.

In a particular embodiment of the invention, the first flexible blade is closer to the second flexible blade than to the third flexible blade.

In a particular embodiment of the invention, the first flexible blade comprises a rigid portion.

In a particular embodiment of the invention, the oscillating mass comprises a flyweight folded in the shape of an elbow.

In a particular embodiment of the invention, the first flexible blade is oblique and connected to the end of the inertia block bent in the shape of an elbow.

According to a particular embodiment of the invention, the second flexible blade is substantially parallel to the longitudinal axis of the oscillating weight, and is connected to the inside of the inertia block bend.

According to a particular embodiment of the invention, the first flexible blade and the second flexible blade form an angle of between 10° and 90°, preferably between 30° and 60°.

In a particular embodiment of the invention, the first flexible blade is U-shaped and is connected to a flyweight of the oscillating mass.

In a particular embodiment of the invention, the first flexible blade is arranged parallel to the longitudinal axis of the oscillating mass.

In a particular embodiment of the invention, the second flexible blade is arranged on an opposite side to the first flexible blade with respect to the oscillating mass.

In a particular embodiment of the invention, the piezoelectric resonator is arranged substantially in the same plane.

In a particular embodiment of the invention, the resonator is configured to cause the mass to oscillate at the resonator's natural frequency.

According to a particular embodiment of the invention, the resonator comprises, preferably for the most part, a non-magnetic mono- or poly-crystalline material with low conductivity, such as silicon, glass, ceramic or a metal, and is obtained, for example, by a MEMS-type photo-lithographic micromachining process.

In a particular embodiment of the invention, the flexible guide is a single piece.

The invention also relates to a piezoelectric motor, in particular for a display device of a timepiece, comprising such a piezoelectric resonator.

In a particular embodiment of the invention, the piezoelectric motor comprises at least one pawl, preferably two pawls, and a moving wheel, the pawl being mounted on the oscillating mass of the piezoelectric resonator so as to rotate the moving wheel in a first direction when the oscillating mass performs its oscillations.

The invention further relates to a timepiece having a timepiece movement comprising a gear transmission configured to rotate at least one hand, and comprising such a piezoelectric motor arranged to actuate the gear transmission.

### BRIEF DESCRIPTION OF THE FIGURES

Other features and advantages will be clear from the description which follows, by way of indication and by no means limitatively, with reference to the annexed drawings, in which:

FIG. 1 schematically represents a top perspective view of a first embodiment of a piezoelectric resonator, in particular for a rotary motor, according to the invention,

FIG. 2 schematically represents a top perspective view of a second embodiment of a piezoelectric resonator, in particular for a rotary motor, according to the invention,

FIG. 3 schematically represents a top view of a third embodiment of a piezoelectric resonator, in particular for a rotary motor, according to the invention,

FIG. 4 schematically represents a top view of a third type of piezoelectric resonator,

FIG. 5 schematically represents a top view of a fourth embodiment of a piezoelectric resonator, in particular for a rotary motor, according to the invention,

FIG. 6 schematically represents a top perspective view of a fifth embodiment of a piezoelectric resonator, in particular for a rotary motor, according to the invention, and

FIG. 7 shows schematically a top view of a rotary piezoelectric motor comprising such a resonator.

### DETAILED DESCRIPTION OF THE INVENTION

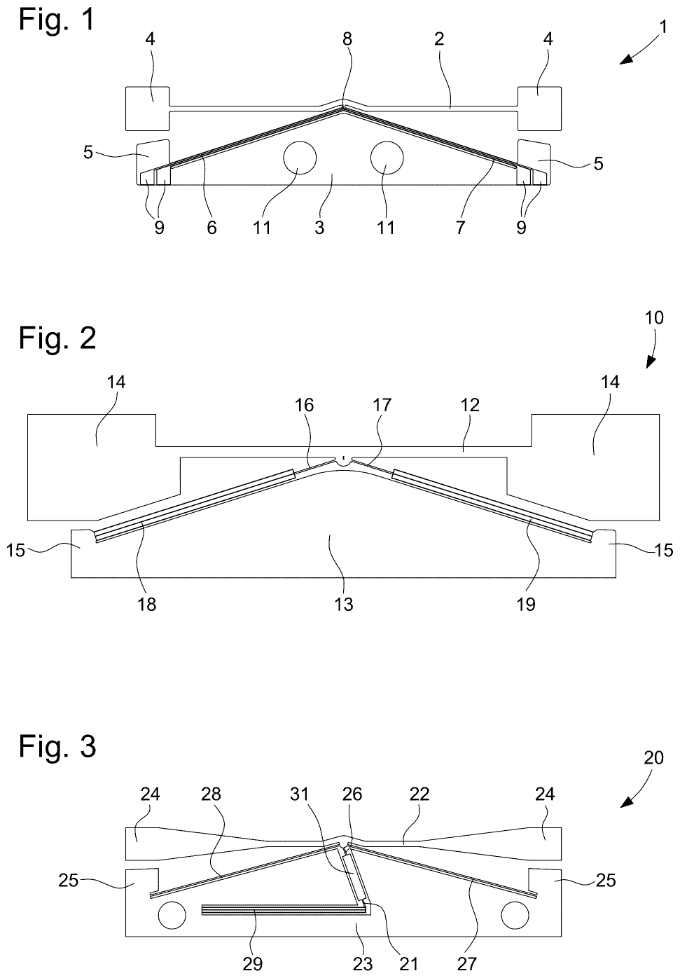

FIGS. 1 to 6 show different versions of a piezoelectric resonator, in particular one used in a rotary motor. In particular, the motor can be used in a timepiece to drive a display device comprising hands arranged on a dial. The piezoelectric resonator 1, 10, 20, 30, 40 preferably extends substantially in one plane.

In FIG. 1, the first embodiment of the piezoelectric resonator comprises a base 3, which here has a substantially triangular, preferably isosceles, shape. The base 3 has two holes 11 so that the base can be assembled on a plate or on a bridge, in particular in a watch movement.

The triangle has a main vertex and two off-centre opposite vertices. The triangle has two equal sides and a base whose length is greater than the height, preferably at least twice as great, or even four or five times as great. The two opposite vertices each have a protrusion 5 extending towards the top of the triangle.

The resonator 1 also comprises an oscillating mass 2. The oscillating mass 2 comprises a main arm at the ends of which are arranged two centrifugal weights 4. The arm comprises a stud 8 arranged in its centre and oriented towards the base 3. The arm is arranged tangentially to the main vertex of the triangle. The arm is substantially straight, except in the middle where it forms a triangular offset to correspond to the main apex of the triangle. The stud 8 is arranged inside the triangular offset.

The oscillating mass 2 and the base 3 are preferably arranged in the same plane.

According to the invention, the resonator comprises a flexible blade guide connecting the oscillating weight 2 to the base 3, so that the oscillating weight 2 can be made to oscillate about a centre of rotation in a pendulum movement. The centre of rotation is arranged substantially in the middle of the oscillating mass 2, i.e. in the middle of the arm, preferably in the centre of mass of the oscillating mass 2. The result is an elastic pivot of the RCC (remote centre compliance) type, which is an elastic rotary guide.

The flexible guide comprises two flexible blades. A first flexible blade 6 and a second flexible blade 7 are connected to the same central part of the oscillating mass 2, in this case the stud 8. The first flexible blade 6 and the second flexible blade 7 are also connected to two opposite eccentric parts of the base 3, in this case the two protrusions 5.

The first flexible blade 6 and the second flexible blade 7 are uncrossed and extend from the stud 8 on the oscillating mass 2 to the projections 5 on the base 3. In this way, each flexible blade 6, 7 connects a projection 5 on the base 3 to the stud 8 on the oscillating mass, running along one of the equal sides of the isosceles triangle.

The first 6 and second 7 flexible blades form a non-zero angle between them, the angle being between 30° and 150°, preferably between 60° and 130°, or even between 90° and 120°.

The flexible blades 6, 7 each comprise a piezoelectric material, which is operable to actuate the flexible blades and cause the oscillating mass to oscillate relative to the base. Preferably, the piezoelectric material is arranged on each flexible blade 6, 7 in its entirety.

For example, the flexible blades have a layer of piezoelectric material sandwiched between two layers of electrodes.

To actuate the flexible blades 6, 7, the protrusions 5 comprise a number of electrical contacts 9 connected to the electrode layers to receive an electrical voltage and actuate the piezoelectric layers of the flexible blades.

The piezoelectric layers are preferably made of a crystalline or polycrystalline material, for example KNN type ceramic (for sodium potassium niobate) or PZT type ceramic (for lead titanium zirconate), with the flexible blades 6, 7 having a thickness that allows them to be deformed.

Thus, by electrically activating the layers of piezoelectric material, the flexible blades 6, 7 alternately deform laterally towards the centre and outwards. Activation is produced with an alternating voltage.

By choosing to actuate the two flexible blades 6, 7 in phase opposition, by reversing the polarity of one blade to the other, the oscillating mass performs small oscillations about the centre of rotation corresponding to the point where the two flexible blades cross, in this case at stud 8. In this way, the oscillating mass 2 oscillates and the two centrifugal weights 4 move laterally at a certain frequency, preferably at the resonance frequency.

In the second embodiment of the resonator 10 shown in FIG. 2, flexible collars narrower than the blades are added. The piezoelectric material is then only located on part 18, 19 of the length of the flexible blades 16, 17. The rest of the resonator 10 is substantially identical to the previous design. Thus, the part of the blades 16, 17 without piezoelectric material is thinner than the part with piezoelectric material, preferably five to ten times thinner.

The base 13 and protrusions 25 are substantially identical to the first design.

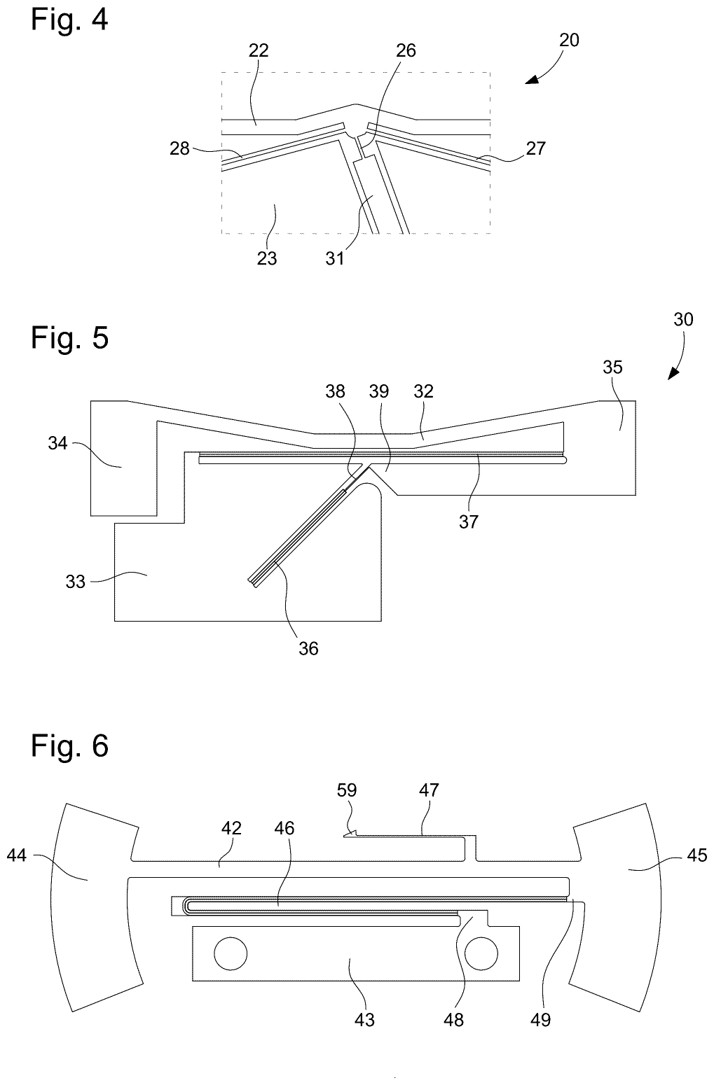

The third embodiment of a resonator 20 in FIGS. 3 and 4 shows a resonator fitted with a flexible guide with three flexible blades 26, 27, 28. The resonator is similar to the first two embodiments in terms of the shape of the base 23 and the protrusions 25.

The base 23 comprises a channel 21 open from the main apex to the interior of the base 23. Channel 21 forms a bend in base 23.

A first flexible blade 26 connects the oscillating mass stud 22 to the base 23 between the second 27 and the third flexible blade 28.

The second 27 and third 28 flexible blades are arranged like the flexible blades of the first and second embodiments. They form a non-zero angle between them, the angle being between 30° and 150°, preferably between 60° and 130°, or even between 90° and 120°, the first flexible blade. In this embodiment, these two flexible blades do not comprise any piezoelectric material. The second 27 and the third 28 are connected to the same central part of the oscillating mass 22 and to two opposite eccentric protrusions 25 of the base 23. The second 27 and the third 28 are uncrossed and extend from the central part, in this case a stud, of the oscillating mass 22 to the eccentric parts of the base 23.

The first flexible blade 26 is activated by electrical contacts mounted on the base 23, not shown in the figures.

The first flexible blade 26 extends into the bent channel 21 to a fixing point at the bottom of the channel 21. The first flexible blade 26 comprises a portion 29 provided with the piezoelectric material at the bottom of the channel 21 after the bend, and a rigid portion 31 at the entrance to the channel 21. The two portions 29, 31 are separated by a flexible neck arranged at the bend.

FIG. 4 is an enlargement of FIG. 3, with the central zone of the first flexible blade 26 being eccentric by a non-zero distance r with respect to the point of intersection of the second flexible blade 27 and the third flexible blade 28, so that when the first flexible blade 26 is actuated, it alternately pulls the oscillating mass 22 to one side and then releases it to cause it to oscillate about a centre of rotation passing through the point of intersection of the first two flexible blades 26, 27.

In the fourth embodiment shown in FIG. 5, the oscillating weight 32 comprises a main arm, a first flyweight 34 at a first end, and a second flyweight 35 at a second end, this second flyweight 35 forming a rigid bend folded under the main arm.

The resonator comprises a flexible guide provided with a first flexible blade 36 connecting the oscillating mass 32 to the base 33, from the end of the bent elbow, the first flexible blade 36 extending into the oblique channel 39 as far as the second embedding point at the bottom of the oblique channel 39.

The flexible guide comprises a second flexible blade 37 extending parallel to the arm of the oscillating mass 32, from a first corner of the base 33 to an embedment point within the folded bend of the oscillating mass 32. The second flexible blade 37 is arranged above the first flexible blade 36.

The base 33 has a first embedding point for the second flexible blade 37, at the level of the first flyweight 34, and a second embedding point arranged here at 45° anticlockwise (non-limiting value), connected to the first flexible blade 36. The second embedding point is arranged in an oblique channel 38 open from a first corner of the base 33.

The first flexible blade 36 and the second flexible blade 37 extend so as to form a non-zero angle of between 10° and 80°, preferably between 30° and 60°, or even between 40° and 50°.

The two flexible blades 36, 37 comprise a piezoelectric material, arranged here entirely on the second flexible blade 37, and partly on the first flexible blade 36. The flexible blades 36, 37 are actuated in the same way as in the previous embodiments, by means of electrical contacts not shown in the figures.

The configuration of this embodiment is different from the other embodiments, but the oscillating mass 32 oscillates in a similar way, i.e. about an axis located at the intersection of the neutral fibres of the two flexible blades 36, 37.

In the fifth embodiment of a piezoelectric resonator 40 shown in FIG. 6, the oscillating mass 42 comprises an arm connecting two centrifugal weights 44, 45. The base 43 is rectangular in shape.

The resonator 40 comprises a first flexible blade 46 in the shape of a U, connecting the oscillating mass 42 to the base 43. The U is arranged parallel to the arm and the base 43. A first end 48 of the U is connected to the base 43, and a second end 49 of the U, extending further from the centre than the first end 48, is connected to a weight 45 of the oscillating mass 42.

The first flexible U-shaped blade 46 comprises a piezoelectric material, preferably along its entire length.

The resonator also comprises a second flexible blade 47 forming an active ratchet blade. The second flexible blade 47 is arranged on the other side of the arm from the first flexible blade 46. Preferably, the second flexible blade 47 does not comprise any piezoelectric material.

By electrically actuating the first flexible U-shaped blade 46, the oscillating mass 42 and the centrifugal weights 44, 45 oscillate about a centre of rotation. Preferably, the centre of rotation is arranged on the centre of gravity of the oscillating mass 42. The first flexible blade 46 is actuated by electrical contacts mounted on the base 43, not shown in the figures.

Resonators 1, 10, 20, 30, according to the methods described above, are preferably mainly made of a monocrystalline or polycrystalline material, such as silicon, glass, ceramic or a metal.

The resonators 1, 10, 20, 30 are obtained, for example, by photo-lithographic micromachining processes of the MEMS (micro-electro mechanical systems) type. The rigidity, elasticity and machining precision of such materials give the resonators 1, 10, 20, 30 a high resonance quality.

In addition, the non-magnetic and low conductivity characteristics of some of these materials provide excellent resistance to high DC and AC magnetic fields.

In addition, the resonators 1, 10, 20, 30 are configured to cause the oscillating mass 2, 12, 22, 32, 42 to oscillate at the natural frequency of the resonator 1, 10, 20, 30, 40, thereby limiting the energy consumption of the resonator, in particular by increasing the angular travel of the oscillating mass.

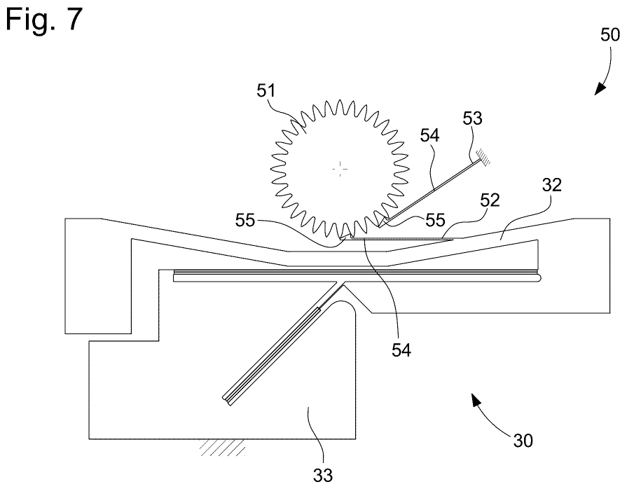

FIG. 7 shows an example of a rotary piezoelectric motor 50, in particular for a display device on a timepiece.

In particular, the motor can be used in a timepiece to drive a display device, such as hands arranged on a dial. The piezoelectric motor 50 is configured so that it can rotate and actuate a mechanical gear transmission of the display device.

The piezoelectric motor 50 comprises a piezoelectric resonator according to the invention, in this case the piezoelectric resonator 30 of the fourth embodiment shown in FIG. 5. The other piezoelectric resonator embodiments can also be used without changing the operation of the piezoelectric motor 50. The piezoelectric resonator 30 is assembled to a plate by its base 33.

The piezoelectric motor 50 also comprises a toothed moving wheel 51 and two pawls 52, 53 configured to rotate the moving wheel 51 in a single direction. The moving wheel 51 preferably comprises peripheral teeth, preferably asymmetrical, which define the direction of rotation. The moving wheel 50 is connected to a gear fitted with the hands of the display device.

The first pawl 52 is active and has the function of rotary the moving wheel 51 in a counter-clockwise direction, while the second pawl 53 is passive and holds the moving wheel 51 when the moving wheel 51 has rotated, while the first active pawl 52 resets on the next tooth of the rotor.

Each pawl 52, 53 has a flexible blade 54 with a tooth 55, preferably asymmetrical, at its end.

Rotation of the moving wheel 51 is generated by movement of the first active pawl 52. The first pawl 52 is mounted on the oscillating mass 32 of the piezoelectric resonator 30. Thus, when the resonator oscillates, the first pawl 52 also oscillates, so that it pushes or pulls the toothed moving wheel 51 in a first direction depending on the positioning of the piezoelectric resonator relative to the moving wheel 51.

The second pawl 53 is either assembled directly on the base or on a base bridge, or more advantageously is integral with the base 30 to limit positioning error due to the sequence of assembly tolerances. Its function is to prevent the toothed wheel from turning in the opposite direction to the first direction. The tooth 55 of the second pawl 53 is configured to cooperate with the asymmetrical teeth, so as to allow the moving wheel 51 to rotate in the first direction, and to block it in the opposite direction.

To this end, the flexible arms 54 of the pawls 52, 53 are in a relaxed straight position, when the tooth 55 is inserted at the bottom of the toothing of the toothed wheel 51, whereas they are cocked and bent, when they are pushed outwards by the toothing, when the toothed wheel 51 rotates in the first direction.

In the case of a watch, the resonance frequency or natural frequency of the motor 50 is adapted to the frequency of the quartz, which is used to regulate the rate of the movement. An excitation frequency is chosen that corresponds to a sub-multiple of the quartz frequency, which is generally 32764 Hz. For example, a frequency of 128 Hz is chosen. The frequency of the motor 50 is preferably adjusted and tuned to the excitation frequency so that its oscillation amplitude does not fall below 90-95% of the maximum amplitude.

Optionally, the second pawl 53 can be configured to act as a pitch sensor, in order to determine the distance or speed of rotation of the moving wheel 51. To this end, the flexible arm 54 of the second pawl 53 is fitted with a piezoelectric material connected to a counting unit. Each time the second pawl 53 is bent, the counting unit registers a rotation of the moving wheel 51 by one tooth.

It will be understood that various modifications and/or improvements and/or combinations obvious to the person skilled in the art may be made to the various embodiments of the invention set out above without departing from the scope of the invention defined by the appended claims.

1. A piezoelectric resonator for a piezoelectric rotary motor, the resonator comprising a stationary base and an oscillating mass extending about a longitudinal axis, the oscillating mass being provided with at least one flyweight, wherein the resonator comprises a flexible blade guide connecting the oscillating mass to the base, so as to be able to oscillate the oscillating weight about a centre of rotation in a pendulum movement, the flexible guide comprising at least one first flexible blade connecting the base to the oscillating weight, the first flexible blade including at least in part an electrically actuable piezoelectric material for deforming the first flexible blade and oscillating the oscillating weight.

2. The piezoelectric resonator as claimed in claim 1, wherein the centre of rotation is arranged substantially in the centre of the oscillating mass.

3. The piezoelectric resonator according to claim 1, wherein the flexible guide comprises a second flexible blade connecting the oscillating mass to the base or to a fixed support.

4. The piezoelectric resonator as claimed in claim 3, wherein the second flexible blade comprises at least in part an electrically actuable piezoelectric material for deforming the second flexible blade and oscillating the oscillating mass.

5. The piezoelectric resonator according to claim 4, wherein the first flexible blade and the second flexible blade form an angle of between 30° and 150°.

6. The piezoelectric resonator as claimed in claim 5, wherein the first flexible blade and the second flexible blade are uncrossed and extend from a central portion of the oscillating mass to eccentric portions of the base.

7. The piezoelectric resonator as claimed in claim 3, comprising a third flexible blade, the second flexible blade and the third flexible blade being uncrossed and extending from a central portion of the oscillating mass to eccentric portions of the base.

8. The piezoelectric resonator according to claim 7, wherein the second flexible blade and the third flexible blade form an angle of between 30° and 150°.

9. The piezoelectric resonator as claimed in claim 8, wherein the first flexible blade is arranged between the second flexible blade and the third flexible blade.

10. The piezoelectric resonator of claim 9, wherein the first flexible blade is closer to the second flexible blade than to the third flexible blade.

11. The piezoelectric resonator as claimed in claim 9, wherein the first flexible blade further comprises a rigid portion.

12. The piezoelectric resonator as claimed in claim 3, wherein the oscillating mass comprises a flyweight bent in the shape of an elbow.

13. The piezoelectric resonator as claimed in claim 12, wherein the first flexible blade is oblique and connected to the end of the flyweight bent in the shape of an elbow.

14. The piezoelectric resonator as claimed in claim 12, wherein the second flexible blade is substantially parallel to the longitudinal axis of the oscillating mass, and is connected to the inside of the elbow of the flyweight.

15. The piezoelectric resonator according to claim 12, wherein the first flexible blade and the second flexible blade form an angle of between 10° and 90°.

16. The piezoelectric resonator as claimed in claim 3, wherein the first flexible blade is U-shaped and is connected to a flyweight of the oscillating mass.

17. The piezoelectric resonator as claimed in claim 16, wherein the first flexible blade is arranged parallel to the longitudinal axis of the oscillating mass.

18. The piezoelectric resonator according to claim 1, wherein the resonator is arranged substantially in the same plane.

19. The piezoelectric resonator according to claim 1, wherein the resonator is configured to cause the oscillating mass to oscillate at the natural frequency of the resonator.

20. A resonator according to claim 1, comprising a non-magnetic monocrystalline or polycrystalline material with low conductivity, such as silicon, glass, ceramic or a metal, and obtained for example by a MEMS-type photo-lithographic micromachining process.

21. A piezoelectric motor for a display device of a timepiece, wherein the piezoelectric motor comprises a piezoelectric resonator according to claim 1.

22. The piezoelectric motor according to claim 21, comprising at least one pawl, and a moving wheel, the pawl being mounted on the oscillating mass of the piezoelectric resonator so as to rotate the moving wheel in a first direction when the oscillating mass performs its oscillations.

23. A timepiece having a timepiece movement comprising a gear transmission configured to rotate at least one hand, wherein the timepiece comprises a piezoelectric resonator according to claim 1, the piezoelectric motor being arranged to actuate the gear transmission.
